(19) United States
(12) Patent Application Publication
(10) Pub. No.: US 2010/0329327 A1
(43) Pub. Date: Dec. 30, 2010

(54) EQUALIZER ADJUSTMENT METHOD AND ADAPTIVE EQUALIZER

(75) Inventors: Hiromu Kato, Kanagawa (JP); Masahiro Takeuchi, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/779,324

(22) Filed: May 13, 2010

(30) Foreign Application Priority Data
Jun. 30, 2009 (JP) 2009-154734

(51) Int. Cl. H03H 7/30; H03K 5/159; H03H 7/40

(52) U.S. Cl. 375/233; 375/232

(57) ABSTRACT

An adaptive equalizer has an equalizer, a sampler, a code comparator, and an eye open/close determinator. The eye open/close determinator makes a determination as to whether a waveform of the input signal has an opening. The code comparator adjusts the equalizer characteristic, with reference to a sampling value by the sampler, and the determination as to whether the waveform has an opening.

This application is based upon and claims the benefit of priority from Japanese patent application No. 2009-154734, filed on Jun. 30, 2009, the disclosure of which is incorporated herein in its entirety by reference.

### BACKGROUND

1. Field of the Invention

The present invention relates to an equalizer adjustment method and an adaptive equalizer.

2. Description of Related Art

While a transmitter transmits data to a receiver using a high-speed serial transmission system, transmission loss increases. Thus, inter-symbol interference (ISI) jitter occurs. The occurrence of ISI jitter reduces the eye opening of the receiver. This is because a transmission line generally exhibits a low-pass filter (LPF) characteristic and therefore a longer transmission line deteriorates high-frequency components more significantly.

Examples of technology that compensates for the deterioration of high-frequency components include mounting of a linear equalizer for adjusting frequency characteristics on the receiver. When the deterioration of high-frequency components caused by the transmission line is approximately equivalent to the emphasis of high-frequency components by the liner equalizer, a signal of good waveform quality (having an optimum eye waveform) can be obtained.

However, when the emphasis of high-frequency components by the linear equalizer is weaker than the deterioration of high-frequency components caused by the transmission line, the ISI jitter is compensated for insufficiently. In contrast, when the emphasis of high-frequency components by the linear equalizer is stronger than the deterioration of high-frequency components caused by the transmission line, a signal having more high-frequency components than required is obtained. For this reason, the user must adjust a characteristic of the linear equalizer, the intensity with which the linear equalizer emphasizes high-frequency components (hereafter referred to as “the equalizer intensity”), to optimum intensity matching the transmission loss. Applications where the user cannot change the settings with respect to the linear equalizer need to have a function of automatically adjusting the equalizer intensity.

Japanese Unexamined Patent Application Publication No. 2008-35485 discloses technology that automatically adjusts the equalizer intensity. FIG. 16 shows the configuration of an adaptive equalizer 40 described in the above-mentioned related-art example. FIG. 17 is a control flow showing an equalizer intensity automatic adjustment operation described in the related-art example. The technology described in the related-art example automatically adjusts the equalizer intensity as follows.

A sampler 474 samples equalizer outputs 46 at clock timings. The sampler 474 then performs data value analysis on the sampling data (S520) and determines whether a data transition has occurred (S530). The sampler 474 then compares a boundary value among the continuous data values containing a transition with 1.5-bit data values preceding the boundary value (S540). The sampler 474 then determines the degree to which the equalizer has compensated for the high-frequency components, based on the comparison (S550) and automatically adjusts the equalizer intensity using an offset controller 476 and an adaptive controller 472.

FIGS. 18A, 18B, and 18C are diagrams showing a specific operating waveform obtained when using the signal adjustment method described in the above-mentioned related-art example. FIG. 18A shows an operating waveform obtained when the equalizer intensity is optimum, FIG. 18B shows that obtained when the equalizer intensity is insufficient, and FIG. 18C shows that obtained when the equalizer intensity is excessive.

When the equalizer intensity is optimum (FIG. 18A), the time width of the center bit data (hereafter also referred to as “one-bit isolated data”) of continuous three-bit data where adjacent data bit values differ from one another equals 1 UI (unit interval), that is, two clock cycles. In this case, the code relationship between data boundary portions E0 and E3 is indeterminate (X).

When the equalizer intensity is insufficient (FIG. 18B), the time width of the one-bit isolated data is smaller than 1 UI. In this case, the code (L) of the boundary portion E2 does not match the code (H) of D3.

When the equalizer intensity is excessive (FIG. 18C), the time width of the one-bit isolated data is larger than 1 UI. In this case, the code (H) of the boundary portion E2 matches the code (H) of D3.

When a data transition occurs, pieces of sampling data (D1, D2, E2, D3) are classified into eight cases shown in FIG. 19. With regard to four of these cases, it is determined that the equalizer intensity is excessive; as for the remaining four cases, it is determined that the equalizer intensity is insufficient. The equalizer intensity is adjusted with reference to these determinations.

For example, for FIG. 18B, (D1, D2, E2, D3)=(−1, -1, -1, +1), so it is determined that “compensation is insufficient” and therefore the equalizer intensity is increased. For FIG. 18C, (D1, D2, E2, D3)=(−1, -1, +1, +1), so it is determined that “compensation is excessive” and therefore the equalizer intensity is reduced. For FIG. 18A, (D1, D2, E2, D3)=(−1, -1, X, +1) and E2 is +1 or -1 with a probability of 50%. Thus, the equalizer intensity is increased with a probability of 50% and is reduced with a probability of 50%. Continuous performance of this operation allows the equalizer intensity to converge on optimum intensity.

### SUMMARY

Unfortunately, a problem occurs when adjusting the following signal using the signal adjustment method described in the above-mentioned related-art example. FIG. 20 shows a case where the equalizer intensity is erroneously automatically adjusted using the signal adjustment method according to the related-art example. The signal of FIG. 20 is data where the one-bit isolated data portion I does not exceed the code determination threshold and where the time width of the two-bit continuous data portions (II and III) is larger than 1 UI and smaller than 2 UI.

A characteristic of the signal shown in FIG. 20 will be described in detail. FIGS. 21A and 21B are drawings showing an example of an eye pattern generated by drawing signal waveforms in a stacking manner. FIG. 21A is a conceptual drawing showing an eye pattern of the signal having a waveform not exceeding the code determination threshold as shown by I of FIG. 20. To stack waveforms not exceeding the code determination threshold generates an eye pattern having no eye opening. Hereafter, such a signal having a waveform that generates an eye pattern having no eye opening will be referred to as a “signal having no opening” or a “signal having an eye closed.”

On the other hand, FIG. 21B is a conceptual drawing of an eye pattern generated from a signal having a waveform exceeding the code determination threshold. Even when stacking an additional signal having a waveform exceeding the code determination threshold, an eye pattern having an eye opening is generated. Hereafter, such a signal having a waveform that generates an eye pattern having an eye opening will be referred to as a “signal having an opening” or a “signal having an eye opened.”

Hereafter, there will be described the operation in a case where the signal adjustment method according to the above-mentioned related-art example is applied to the signal of FIG. 20, that is, the signal having an eye closed to adjust the equalizer intensity automatically.

The sampling result of the one-bit isolated data portion 1 is (D1, D2, E2, D3)=(−1, −1, −1, −1). This data does not match any of the data pieces shown in FIG. 19, so the equalizer intensity is not adjusted.

The sampling result of the two-bit isolated data portion II is (D1, D2, E2, D3)=(−1, -1, +1, +1). With regard to this data, it is determined that “compensation is excessive,” at the equalization level section of the table shown in FIG. 19. For this reason, although the offset should be actually increased to make the data into two-bit data, the equalizer intensity is erroneously reduced oppositely.

As for the III portion, which lags behind the II portion by an interval of 1 UI, the sampling result thereof is (D1, D2, E2, D3)=(−1, +1, +1, -1). With regard to this sampling result, it is determined that “compensation is probably excessive,” at the equalization level section of the table shown in FIG. 19. For this reason, although the equalizer intensity should be originally increased, it is erroneously reduced oppositely.

As seen, when the signal adjustment method according to the above-mentioned related-art example is applied to the signal shown in FIG. 20, the equalizer intensity is kept low and is not automatically adjusted so that it is increased. Incidentally, if the highest value is set for the equalizer intensity as the initial value and then lower values are set sequentially, the equalizer intensity can converge on optimum intensity. However, when the setting of the equalizer intensity varies due to noise, abnormal operation, or the like and the above-mentioned state thus occurs, the equalizer intensity is kept low as well. In this case, the user must reset the equalizer so that it operates normally.

An equalizer adjustment method according to an aspect of the present invention is an equalizer adjustment method for adjusting a characteristic of an equalizer that adjusts a level of an input signal. The equalizer adjustment method includes: selecting a first timing on the basis of a data transition of the input signal and selecting second and third timings in accordance with cycles of the input signal, the second timing being a given time before the first timing, the third timing being a given time after the first timing; performing sampling of the input signal at the first timing; detecting three-bit data from sampling data extracted in the sampling at the first timing, the three-bit data being data where values of adjacent data bits differ from one another; performing sampling of the input signal at the second timing; performing sampling of the input signal at the third timing; making a determination as to whether a waveform of the input signal has an opening; and when the three-bit data is detected, adjusting the equalizer characteristic with reference to a value obtained in the sampling performed at the first timing, a value obtained in the sampling performed at the second timing, a value obtained in the sampling performed at the third timing, and the determination as to whether the waveform has an opening.

According to the present invention, when one-bit isolated data is detected, the equalizer intensity is adjusted with reference to a determination using sampling values, as well as a determination as to whether the eye of a signal to be adjusted is opened. Accordingly, the invention can provide an equalizer adjustment method that does not erroneously adjust the equalizer intensity.

The present invention allows, even when the eye of a signal to be adjusted is not opened, automatically adjusting the equalizer intensity without erroneously reducing it.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a diagram showing the basic configuration according to a first embodiment of the present invention;

FIG. 2 is a drawing showing the logic operation of a code comparator according to the first embodiment;

FIG. 3 is a flowchart showing the basic operation according to the first embodiment;

FIG. 4 is a diagram showing a sampling result according to the first embodiment, where compensation by the equalizer is insufficient;

FIG. 5 is a diagram showing a sampling result according to the first embodiment, where compensation by the equalizer is excessive;

FIG. 6 is a diagram showing a sampling result according to the first embodiment, where compensation by the equalizer is optimum;

FIG. 7 is a diagram showing the configuration of an eye open/close determinator according to the first embodiment;

FIG. 8 is a flowchart showing the operation of the eye open/close determinator according to the first embodiment;

FIG. 9 is a timing chart of the operation of the eye open/close determinator according to the first embodiment;

FIG. 10 is a diagram showing the operation in a case where an equalizer adjustment method according to the first embodiment is applied to an equalizer output signal that causes a misoperation conventionally;

FIG. 11 is a flowchart showing the basic operation according to a second embodiment;

FIG. 12 is a drawing showing the logic operation of a code comparator according to the second embodiment;

FIG. 13 is a diagram showing the basic configuration according to a third embodiment of the present invention;

FIG. 14 is a flowchart showing the operation of an eye open/close determinator according to the third embodiment;

FIG. 15 is a timing chart of the operation of the eye open/close determinator according to the third embodiment;

FIG. 16 is a diagram showing the basic configuration according to the related art;

FIG. 17 is a flowchart showing the basic operation according to the related art;

FIG. 18A is a diagram showing a sampling result of an equalizer output signal according to the related art;

FIG. 18B is a diagram showing a sampling result of an equalizer output signal according to the related art;

FIG. 18C is a diagram showing a sampling result of an equalizer output signal according to the related art;

FIG. 19 is a table showing an equalizer gain control method according to the related art;

FIG. 20 is a diagram showing an equalizer output signal causing a misoperation in the signal adjustment method according to the related art;

FIG. 21A is a conceptual diagram related to the open and close of an eye; and

FIG. 21B is a conceptual diagram related to open and close of an eye.

### DETAILED DESCRIPTION OF THE EXEMPLARY EMBODIMENTS

### First Embodiment

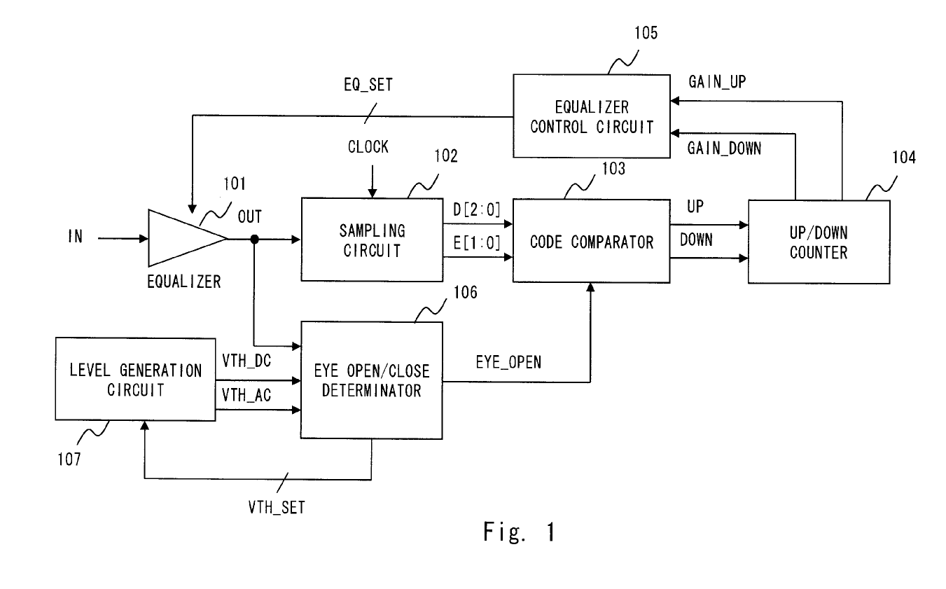

Now. embodiments of the present invention will be described with reference to the accompanying drawings. First, referring to FIG. 1, the basic configuration of a first embodiment of the present invention will be described. The basic configuration shown in FIG. 1 includes an equalizer 101, a sampling circuit 102, a code comparator 103, an up/down counter 104, an equalizer control circuit 105, an eye open/close determinator 106, and a level generation circuit 107.

The equalizer 101 receives an input signal from a transmitter (not shown) and shapes the input signal with specified equalizer intensity. Upon receipt of an EQ_SET signal (equalizer intensity setting signal) from the equalizer control circuit 105, the equalizer 101 changes the degree of emphasis of high-frequency components monotonously.

The sampling circuit 102 samples a signal outputted from the equalizer 101 at input clock timings. Sampling is performed at a data transition timing (hereafter also referred to as an “edge timing”) and at a timing shifted from the edge timing by 0.5 UI or so (hereafter also referred to as a “data timing”). More specifically, a data timing lagging behind the edge timing by 0.5 UI or so is referred to as a first timing and sampling is performed at the first timing. The sampling circuit 102 obtains data E[1:0] by coding the values at two edge timings, timings 0.5 UI or so before and after the first timing, and outputs E[1:0] to the code comparator 103. The sampling circuit 102 also obtains data D[2:1] by coding the value at the first timing and the values at two data timings 1 UI or so before and after the first timing, and outputs D[2:1] to the symbol comparator 103. The timing 0.5 UI before the first timing is referred to as a second timing, and the timing 0.5 UI after the first timing is referred to as a third timing. The code comparator 103 (to be described later) adjusts the equalizer intensity using the sampling values at the first, second, and third timings. The operation of the code comparator 103 will be described in detail later.

In this embodiment, an example is described where the sampling circuit 102 outputs data obtained by coding sampling values and the coded data is used to adjust the equalizer intensity; however, this embodiment is not limited thereto. The above-mentioned coding process is only illustrative, and use of sampling values allows, even when the eye of a signal to be adjusted is not open, automatically adjusting the equalizer intensity with erroneously lowering it.

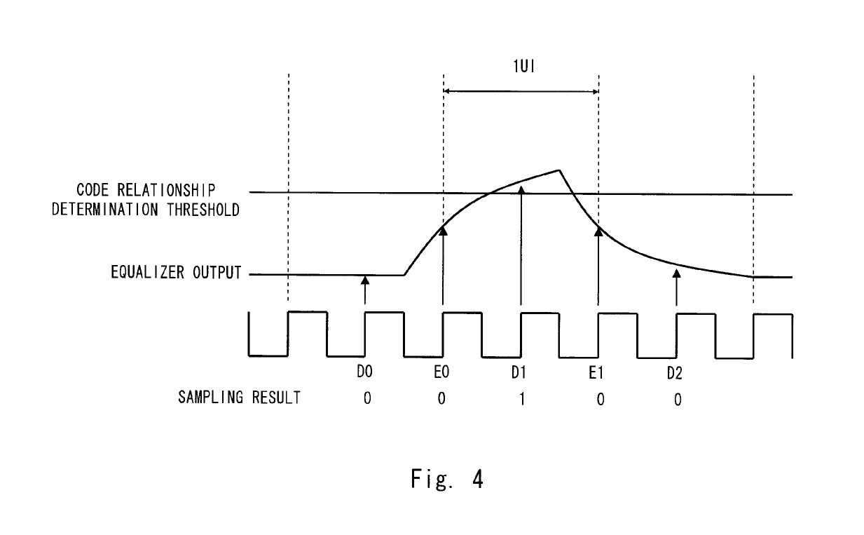

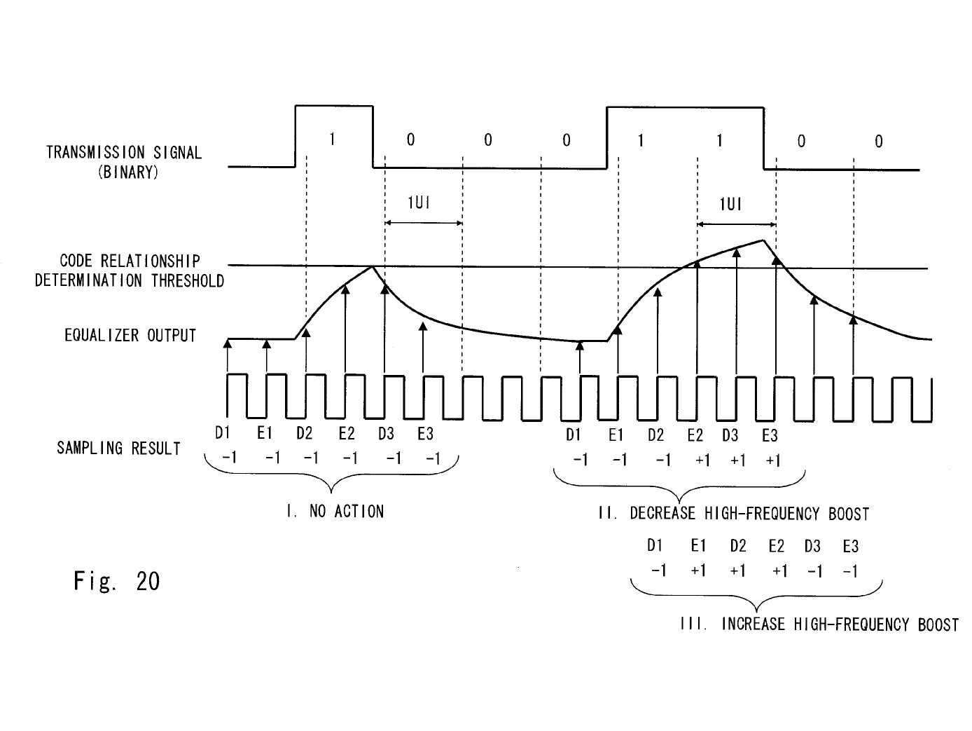

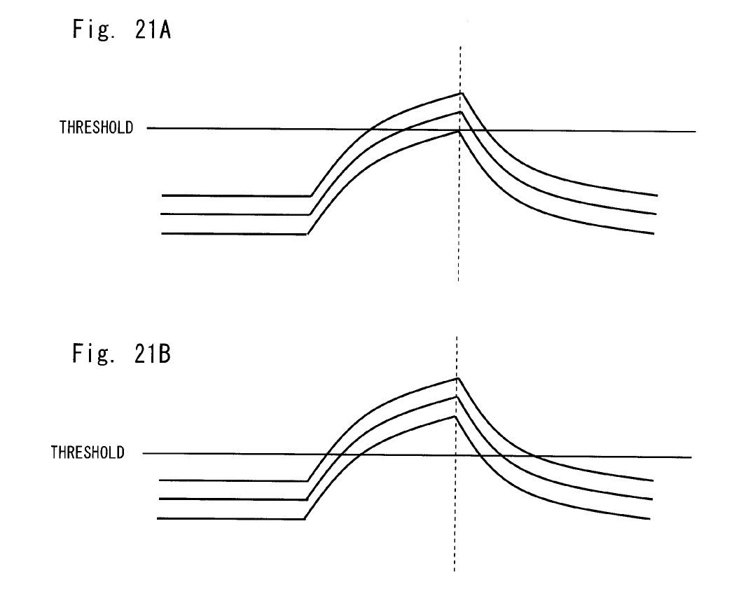

The sampling circuit 102 performs sampling at the rising timings of clocks in FIGS. 4, 20, and like, but not limited thereto. For example, if sampling can be performed at both edge timings and data timings, sampling may be performed at both the rising and falling timings of clocks. Also, if sampling can be performed at edge timings and at data timings, sampling may be performed at the rising, falling, or both timings of multi-phase clocks.

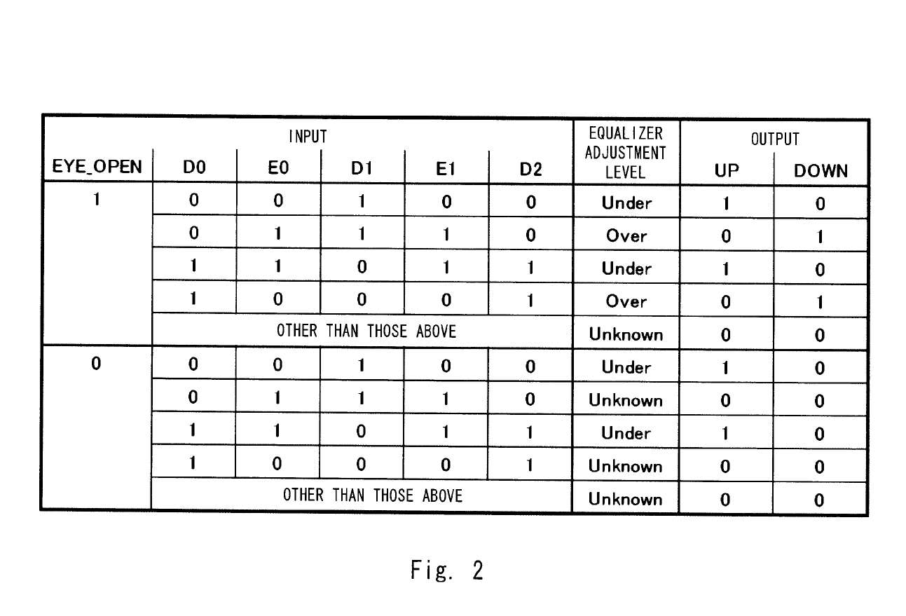

The code comparator 103 receives E[1:0] and D[2:0] from the sampling circuit 102. The code comparator 103 also receives an EYE_OPEN signal from the eye open/close determinator 106. The code comparator 103 then performs a data pattern analysis using E[1:0], D[2:0], and the EYE_OPEN signal. FIG. 2 is a table showing the logic operation of the code comparator 103. Based on a specific data pattern and the EYE_OPEN signal, the code comparator 103 determines whether the equalizer intensity is optimum. When determining that the equalizer intensity is insufficient, the code comparator 103 outputs UP=“1” to the up/down counter 104. When determining that the equalizer intensity is excessive, the code comparator 103 outputs DOWN=“1” to the up/down counter 104.

The code comparator 104 counts the respective numbers of inputs of UP=“1” and DOWN=“1” received from the code comparator 103. The up/down counter 104 has thresholds N and M, which have been set in advance and are integers of one or more. If (number of inputs of UP=“1”)−(number of inputs of DOWN=″1″)=N (overflow), the up/down counter 104 outputs GAIN_UP=“1” to the equalizer control circuit 105, as well as is cleared. If (number of inputs of DOWN=“1”)−(number of inputs of UP=“1”)=M (underflow), the up/down counter 104 outputs GAIN_DOWN=“1” to the equalizer control circuit 105, as well as is cleared. The user may change the values of the thresholds N and M as appropriate.

When receiving GAIN_UP=“1”, the equalizer control circuit 105 outputs an EQ_SET signal for increasing the equalizer intensity, to the equalizer 101. When receiving GAIN_DOWN=“1”', the equalizer control circuit 105 outputs an EQ_SET signal for reducing the equalizer intensity, to the equalizer 101.

The eye open/close determinator 106 determines whether the eye of the signal outputted from the equalizer 101 is opened or closed, using two reference potentials (VTH_DC, VTH_AC) generated in the level generation circuit 107. If the eye is opened, the eye open/close determinator 106 outputs EYE_OPEN=“1” to the code comparator 103. In contrast, if the eye is closed, the eye open/close determinator 106 outputs EYE_OPEN=“0” to the code comparator 103.

The reference potentials (VTH_DC, VTH_AC) from the level generation circuit 107 are automatically adjusted to the level according to the amplitude of the signal outputted from the equalizer 101, based on a VTH_SET signal from the eye open/close determinator 106.

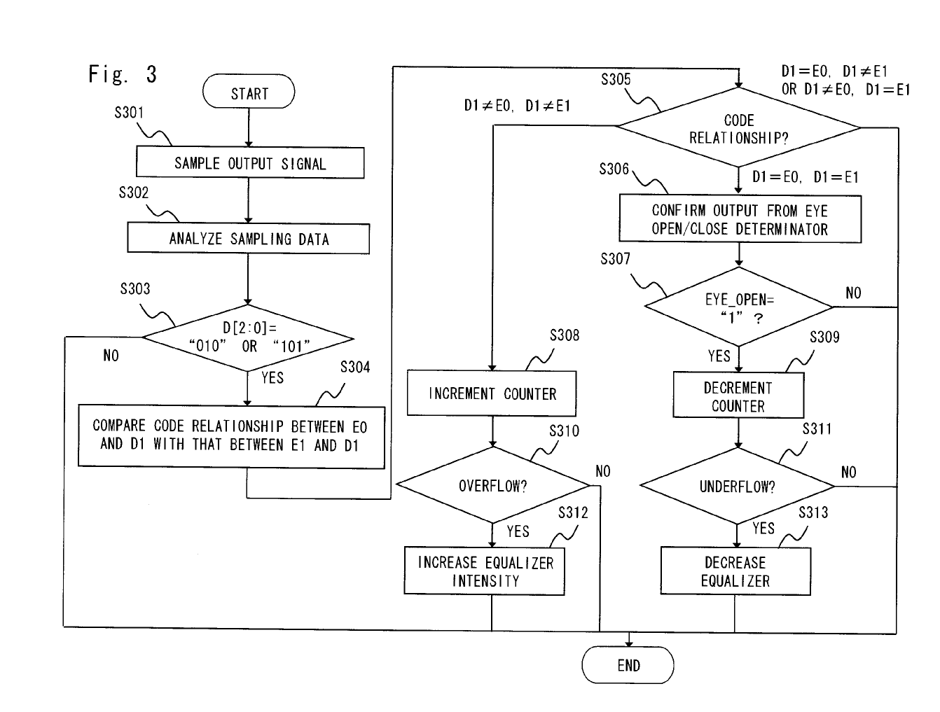

Next, the equalizer intensity automatic adjustment operation according to this embodiment will be described with reference to the flowchart of FIG. 3. The sampling circuit 102 samples a signal outputted from the equalizer 101 at clock timings (S301). As described above, sampling is performed at data transition timings.

Next, the code comparator 103 analyzes the sampling data D[2:0] (S302, S303). If D[2:0], that is, the bit string of the three data timings is “101” or “010,” it is determined that one-bit isolated data has been inputted. If D[2:0] is other than “101” and “010,” it is determined that no one-bit isolated data has been inputted and therefore the equalizer intensity is not adjusted (S303: No).

If one-bit isolated data has been inputted (S303: Yes), the code comparator 103 compares the code relationship between E0 and D1 with that between E1 and D1 (S304, S305). FIG. 4 shows the waveform of one-bit isolated data outputted from the equalizer 101 when the equalizer intensity is insufficient. Since the time width of the one-bit isolated data of FIG. 4 is smaller than 1 UI, the code relationship between E0 and D1 is E0±D1. The code relationship between E1 and D1 is E1±D1. When the code relationships E0±D1 and E1±D1 are detected (S305), UP=“1” is inputted into the up/down counter 104 (S308).

When (number of inputs of UP=“1”)−(number of inputs of DOWN=“1”) reaches the given number (N), that is, an overflow occurs (S310) while the up/down counter 104 is incremented (S308), the up/down counter 104 outputs GAIN_UP, and the equalizer control circuit 105 outputs an intensity setting signal EQ_SET for increasing the equalizer intensity, to the equalizer 101 (S312).

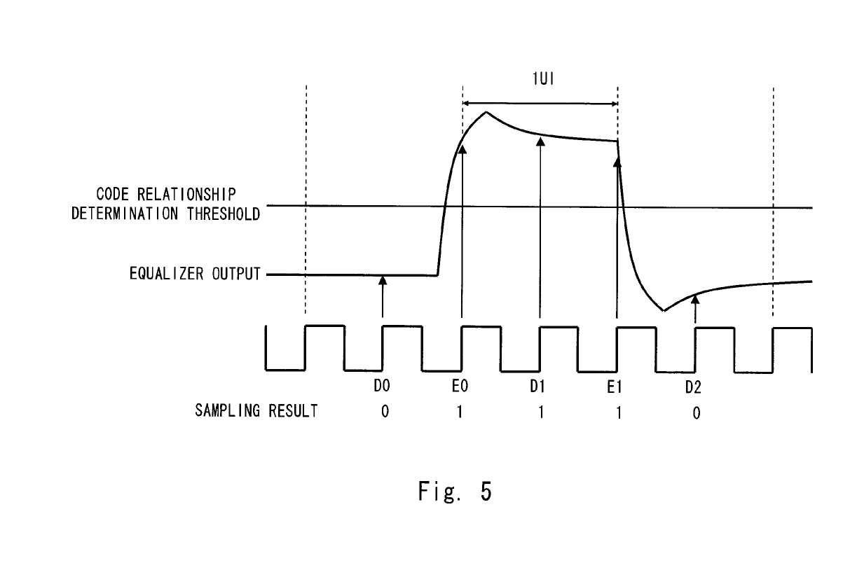

FIG. 5 shows the waveform of one-bit isolated data outputted from the equalizer 101 when the equalizer intensity is excessive. Since the time width of the one-bit isolated data of FIG. 5 is larger than 1 UI, the code relationship between E0 and D1 is E0=D1. The code relationship between E1 and D1 is E1=D1 (S305: Yes).

Incidentally, when a malfunction occurs using the signal adjustment method described in the above-mentioned related-art example, that is, when data as shown in FIG. 20 is inputted, the code comparator 103 determines that the code relationship between E0 and D1 is E0=D1 and that the code relationship between E1 and D1 is E1=D1 (S305: Yes).

In this case, the code comparator 103 refers to the code of EYE_OPEN, the eye open/close determination result received from the eye open/close determinator 106 (S306). If the equalizer intensity is excessive, the eye is opened. On the other hand, for an input signal having a waveform as shown in FIG. 20, its eye is closed. This allows, based on whether the eye is opened or closed, distinguishing a case where the equalizer intensity is excessive from a case where a signal having a waveform as shown in FIG. 2 has been inputted.

When EYE_OPEN=“0”, that is, when the eye is closed, automatic adjustment of the equalizer intensity is not performed (S307: No). In contrast, if EYE_OPEN=“1,” that is, when the eye is opened, the code comparator 103 determines that equalizer intensity is excessive, and then outputs DOWN=“1” to the up/down counter 104 (S309).

When (number of inputs of DOWN=“'1”)−(number of inputs of UP=“1”) reaches the given number (M), that is, when an underflow occurs (S311) while the up/down counter 104 is decremented (S309), the up/down counter 104 outputs GAIN_UP, and the equalizer control circuit 105 outputs an intensity setting signal EQ_SET for reducing the equalizer intensity, to the equalizer 101 (S313).

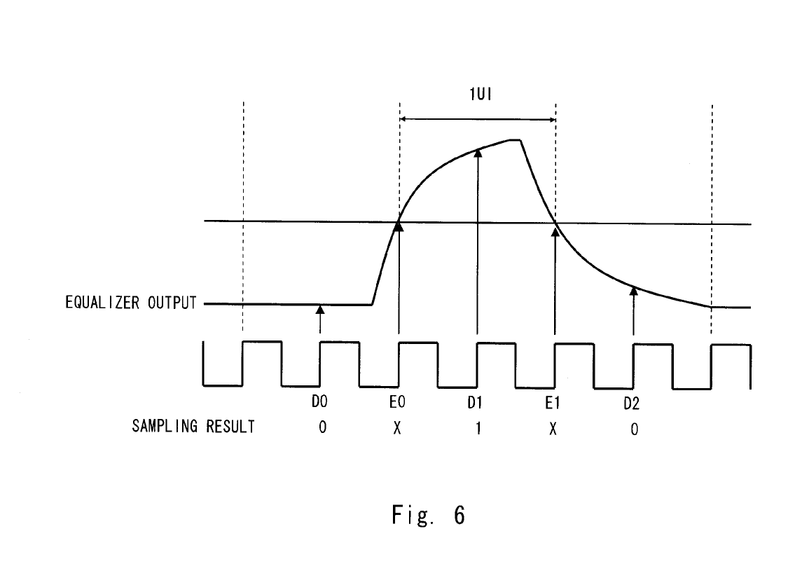

FIG. 6 shows the waveform of one-bit isolated data outputted from the equalizer 101 when the equalizer intensity is optimum. The time width of the one-bit isolated data of FIG. 6 equals 1 UI. In this case, the code relationship between E0 and D1 is indeterminate. Specifically, the code of E0 is 0 or 1 with a probability of 50% and therefore the probability that the code relationship between E0 and D1 is E0=D1 equals the probability that it is E0 D1. Similarly, the code relationship between E1 and D1 is indeterminate. Specifically, the code of E1 is 0 or 1 with a probability of 50% and therefore the probability that the code relationship between E1 and D1 is E1=D1 equals the probability that it is E1±D1. Accordingly, the number of inputs of UP=“1” (S308) equals the number of inputs of DOWN=“1” (S309), so the equalizer intensity of the equalizer 101 converges on optimum intensity.

Performance of the above-mentioned process steps realizes the equalizer intensity automatic adjustment according to this embodiment. Performance of this process allows the equalizer intensity to converge on optimum intensity. However, in the state of convergence, the equalizer intensity may vary and thus ISI jitter may occur in a signal outputted from the equalizer 101. In this case, the above-mentioned series of process steps may be stopped after a given period to prevent a variation in equalizer intensity.

Whether the eye of a signal outputted from the equalizer 101 is opened or closed is determined based on the peak level of high-frequency components (S_AC) of the output signal. If the eye of the output signal is closed, it means that the high-frequency components of the signal have been attenuated and therefore the peak level of the high-frequency components (S_AC) is low. In contrast, if the eye of the output signal is opened, it means that the high-frequency components of the signal are many large and therefore the peak level of the high-frequency components (S_AC) is high.

The peak level of the high-frequency components (S_AC) of the output signal varies with the amplitude of the signal. For this reason, there is a need to automatically adjust the reference potentials (VTH_DC, VTH_AC) so that the counter 1065 becomes a determination level corresponding to the amplitude of the output signal. This will be detailed in the explanation of the eye open/close determinator 106.

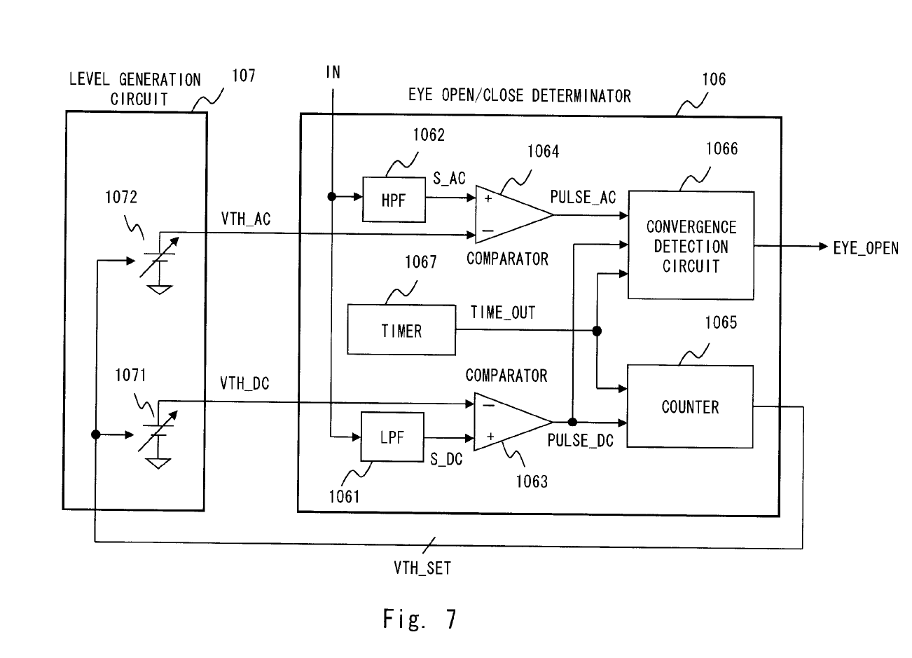

The eye open/close determinator 106 and level generation circuit 107 will be described. FIG. 7 is a diagram showing an example of the specific configuration of the eye open/close determinator 106 and level generation circuit 107. An LPF 1061 extracts low-frequency components S_DC of an input signal IN, which is a signal outputted from the equalizer 101. An HPF 1062 extracts high-frequency components S_AC of the input signal IN.

A comparator 1063 compares S_DC with a voltage VTH_DC (threshold voltage) generated by a variable voltage source 1071 included in the level generation circuit 107. If the peak level of S_DC is higher than VTH₁₃DC (S_DC peak level >VTH_DC), the comparator 1063 outputs a pulse train PULSE_DC. In contrast, if the peak level of S_DC is lower than VTH_DC (S_DC peak level <(VTH_DC), the comparator 1063 outputs “0.”

A comparator 1064 compares S_AC with a voltage VTH_AC (threshold voltage) generated by a variable voltage source 1072 included in the level generation circuit 107. If the peak level of S_AC is higher than VTH_AC (S_AC peak level >(VTH_AC), the comparator 1064 outputs a pulse train PULSE_AC. In contrast, if the peak level of S_AC is lower than VTH_AC (S_AC peak level <VTH_AC), the comparator 1064 outputs “0.”

A counter 1065 receives PULSE_DC from the comparator 1063 and a TIME_OUT signal from a timer 1067. The counter 1065 outputs an adjustment signal VTH_SET to the variable voltage sources 1071 and 1072. When receiving PULSE_DC P or more times (P is any integer of one or more), the counter 1065 raises VTH_SET and outputs the raised VTH_SET. Also, when receiving the TIME_OUT signal, the counter 1065 lowers the VTH_SET signal and outputs lowered VTH_SET.

A convergence detection circuit 1066 receives PULSE_DC from the comparator 1063, PULSE_AC from the comparator 1064, and TIME_OUT from the timer 1067. The convergence detection circuit 1066 determines whether the levels of VTH_DC and VTH_AC have converged and outputs an EYE_OPEN signal. The timer 1067 outputs the TIME_OUT signal to the counter 1065 and convergence detection circuit 1066 at every given time.

In the level generation circuit 107, the variable voltage sources 1071 and 1072 previously generate the voltages VTH_DC and (VTH_AC in such a manner that these voltages are proportionate with each other.

If the number of changes made to VTH_SET by the counter 1065 during one cycle of TIME_OUT falls with any range, the convergence detection circuit 1066 sets “1” for a convergence flag signal LOCK. If the number of changes of VTH_SET is n (n is a natural number), n×P<(number of inputs of PULSE_DC)<(n+1)×P. Accordingly, counting the number of inputs of PULSE_DC during one cycle of a TIME_OUT signal allows determining whether the level of VTH_DC has converged, thereby setting the convergence flag signal LOCK.

When LOCK is “1” and when the convergence detection circuit 1066 receives PULSE_AC Q times (Q is any integer of one or more), the convergence detection circuit 1066 determines whether the eye is opened and outputs EYE_OPEN=“1.”

The reason why a signal level determination is made when LOCK is 1, that is, when the level of VTH_DC has converged is as follows. If the peak level of S_DC is significantly higher than VTH_DC (S_DC peak level >VTH_DC), VTH_AC is significantly lower than the optimum level, since VTH_AC is proportionate with VTH_DC. For this reason, even when the eye of the signal outputted from the equalizer 101 is closed, the comparator 1064 may output the pulse train PULSE_AC. In contrast, if the peak level of S_DC is lower than VTH_DC (S_DC peak level <VTH_DC), VTH_AC is significantly higher than the optimum level, since VTH_AC is proportionate with VTH_DC. For this reason, even when the eye of the output signal from the equalizer 101 is opened, the output from the comparator 1064 may be fixed to “0”

If the peak level of S_AC is lower than VTH_AC (S_AC peak level <(VTH_AC, the output from the comparator 1064 is fixed to “0”) when VTH_DC has converged around the peak level of S_DC, the convergence detection circuit 1066 determines that the eye is closed. In contrast, if the peak level of S_AC is higher than VTH_AC (S_AC peak level >VTH_AC, the output from the comparator 1064 is the pulse train PULSE_AC) when VTH_DC has converged around the peak level of S_DC, the convergence detection circuit 1066 determines that the eye is opened.

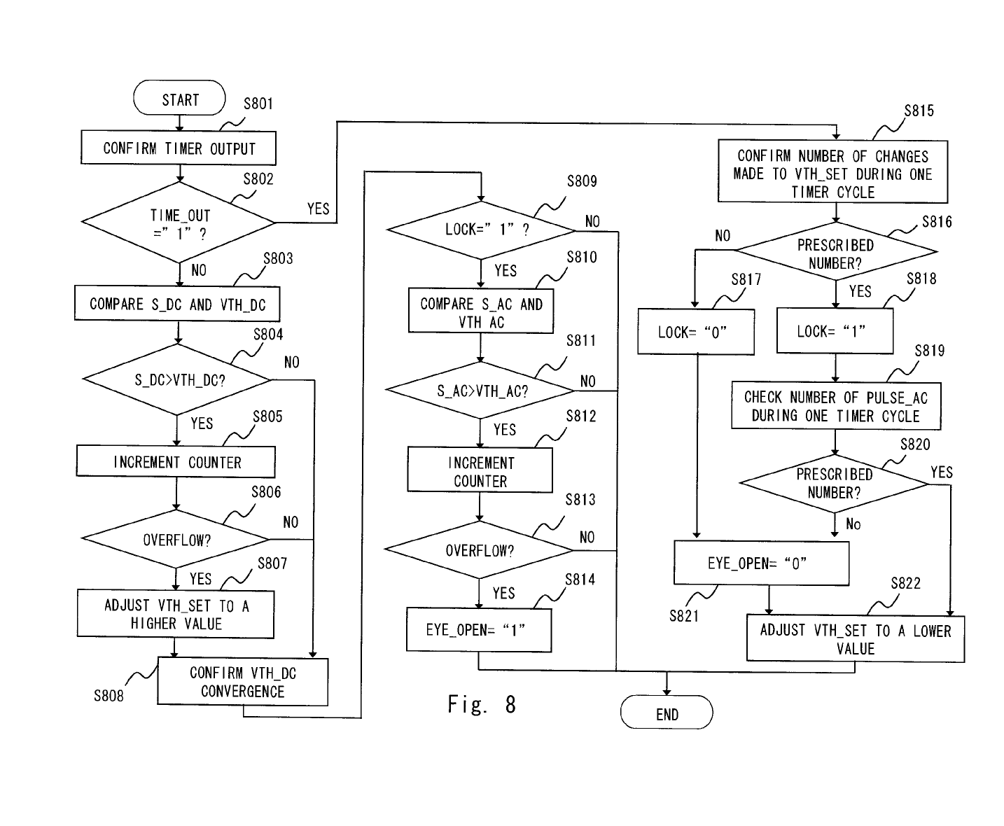

Next, the signal level determination operation of the eye open/close determinator 106 will be described with reference to the flowchart of FIG. 8.

The timer 1067 outputs a TIME_OUT signal at every given time (S801). If TIME_OUT is not “1” (S802: No) and if the comparator 1063 outputs the pulse train (PULSE_DC), the counter 1065 is incremented by one (S802 to S805). When receiving PULSE_DC times equal to or more than the threshold (P times) (overflow), the counter 1065 changes the adjustment signal VTH_SET to a higher value (S806, S807).

When VTH_DC has converged, that is, when the flag signal LOCK inside the convergence detection circuit 1066 is “1” (S808, S809), the convergence detection circuit 1066 determines whether the eye is opened or closed.

The convergence detection circuit 1066 compares S_AC with VTH_AC. When S_AC is larger, that is, when the convergence detection circuit 1066 receives PULSE_AC from the comparator 1064, it increments the number of inputs of PULSE_AC (S810 to S812). When receiving PULSE_AC times equal to the threshold (Q times) (overflow), the convergence detection circuit 1066 determines that the eye is opened. If the eye is opened, the convergence detection circuit 1066 outputs a signal (EYE_OPEN=“1”) indicating that the eye is opened (S813, S814).

In contrast, when the signal TIME_OUT outputted from the timer 1067 is “1,” the convergence detection circuit 1066 determines that the levels of VTH_DC and VTH_AC have converged (S802: Yes).

If the number of changes made to the VTH_SET signal by the counter 1065 during one cycle of the TIME_OUT signal falls within any range, the convergence detection circuit 1066 determines that the levels of VTH_DC and VTH_AC have converged. The convergence detection circuit 1066 then sets “1” for its internal convergence flag signal LOCK (LOCK=“1”) (S815, S816, S818).

If LOCK=“1” and if the number of inputs of PULSE_AC during one cycle of the timer is a prescribed number of times or less, the convergence detection circuit 1066 determines that the high-frequency components of the input signal IN from the equalizer 101 is insufficient. The prescribed number of times for use in determination of the number of inputs of PULSE_AC is any integer of one or more and may be changed as appropriate. When determining that the high-frequency components of the input signal IN from the equalizer 101 is insufficient, the convergence detection circuit 1066 outputs a signal (EYE_OPEN=“0”) indicating that the eye is closed (S820, S821).

If the number of changes made to the VTH_SET signal by the counter 1065 during one cycle of the TIME_OUT signal is out of any range, the convergence detection circuit 1066 determines that the levels of VTH_DC and VTH_AC have not converged yet. The convergence detection circuit 1066 then sets “0” for its internal convergence flag signal LOCK (S817). The convergence detection circuit 1066 also outputs a signal (EYE_OPEN=“0”) indicating that the eye is closed (S821).

Finally, the counter 1065 sets a one-step-lower value for VTH_SET (S822). As seen, when the input signal from the equalizer 101 has a large amplitude, the levels of VTH_DC and VTH_AC are raised. In contrast, when the input signal from the equalizer 101 has a small amplitude. the levels of VTH_DC and VTH_AC are lowered. Continuing the above-mentioned process allows VTH_DC to converge around the peak level of S_DC. In the end, VTH_DC and VTH_AC are automatically adjusted to optimum levels. Also, performance of the above-mentioned process (S801 to 5822) allows the eye open/close determinator 106 to determine in real time whether the eye of the signal outputted from the equalizer 101 is opened or closed.

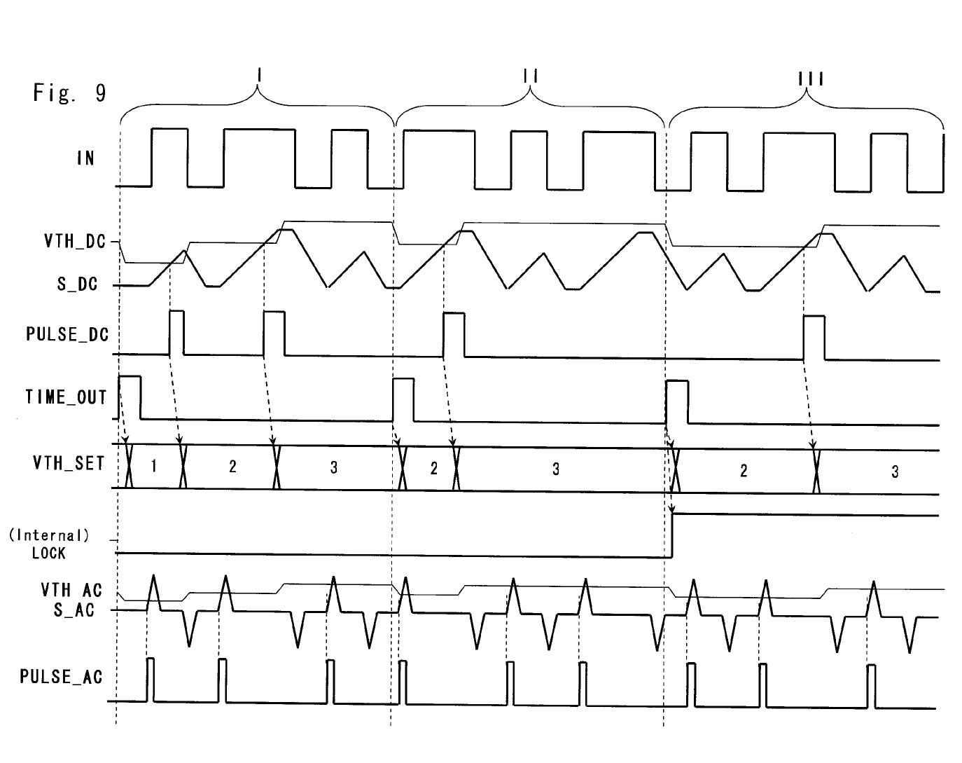

Next, the operation of the eye open/close determinator 106 will be described with reference to the timing chart of FIG. 9. FIG. 9 shows the operation of the eye open/close determinator 106 during three cycles (I, II, and III of FIG. 9) of the TIME_OUT signal.

In an example shown in FIG. 9, the counter 1065 changes the value of VTH_SET each time PULSE_DC is inputted (P=1). Also, when PULSE_AC is inputted one or more times (Q=1), the convergence detection circuit 1066 determines that the eye is opened. The condition for determining that VTH_DC has converged is that “the number of changes made to VTH_SET by the counter 1065 during one cycle of the TIME_OUT signal is one (n=1).” Also, it is assumed that the value of LOCK, the convergence flag signal of the convergence detection circuit 1066 is “0” in the cycle of FIG. 9.

The operation of the eye open/close determinator 106 in the cycle I of FIG. 9 will be described. The comparator 1063 compares the peak level of S_DC with VTH_DC. When the peak level of S_DC exceeds VTH_DC, the comparator 1063 outputs PULSE_DC to the counter 1065.

Upon receipt of PULSE_DC, the counter 1065 changes VTH_SET to a higher value. Specifically, receipt of PULSE_DC changes VTH_SET to a one-step-higher value “2”. This raises the levels of VTH_DC and VTH_AC.

Similarly, when the peak level of S_DC exceeds VTH_DC, the comparator 1063 outputs PULSE_DC to the counter 1065 again. Upon receipt of PULSE_DC, the counter 1065 changes VTH_SET to a still higher value “3”. This raises the levels of VTH_DC and VTH_AC.

In the cycle I of FIG. 9A, the peak level of S_AC exceeds VTH_AC and therefore the comparator 1064 outputs PULSE_AC to the convergence detection circuit 1066. In this case, LOCK=“0”, so the convergence detection circuit 1066 outputs EYE_OPEN=“0.”

Next, the operation of the eye open/close determinator 106 in the cycle II of FIG. 9 will be described. The timer 1067 inputs the TIME_OUT signal to the counter 1065. Upon receipt of the TIME_OUT signal, the counter 1065 changes VTH_SET to the one-step-lower value “2”. This lowers the levels of VTH_DC and VTH_AC.

The counter 1065 has changed the setting of VTH_SET twice in the cycle I of FIG. 9 (“1”-“2”-“3”), so the convergence detection circuit 1066 determines that the level of VTH_DC has not converged yet. Accordingly, the value of LOCK is not changed (LOCK=“0”).

When the peak level of S_DC exceeds VTH_DC, the comparator 1063 outputs PULSE_DC to the counter 1065. Specifically, receipt of PULSE_DC changes VTH_SET to the one-step-higher value “3”. This raises the levels of VTH_DC and VTH_AC.

In the cycle II of FIG. 9, the peak level of S_AC exceeds VTH_AC and therefore the comparator 1064 outputs PULSE_AC to the convergence detection circuit 1066. In this case, LOCK=“0”, so the convergence detection circuit outputs EYE_OPEN=“0”, as in the cycle I of FIG. 9.

Next, the operation of the eye open/close determinator 106 in the cycle III of FIG. 9 will be described. Upon receipt of the TIME_OUT signal, the counter 1065 changes VTH_SET to the one-step-lower setting “2”, as in the cycle II of FIG. 9.

The counter 1065 has changed the setting of VTH_SET (“2“−”3”) once in the cycle II of FIG. 9, so the convergence detection circuit 1066 determines that the level of VTH_DC has converged. Accordingly, the convergence detection circuit 1066 sets “1” for its internal convergence flag signal LOCK (LOCK=“1”).

When S_AC exceeds VTH_AC, the comparator 1064 outputs PULSE_AC to the convergence detection circuit 1066. Since the convergence detection circuit 1066 receives PULSE_AC when LOCK=“1”, it determines that the eye is opened and outputs EYE_OPEN “1.”

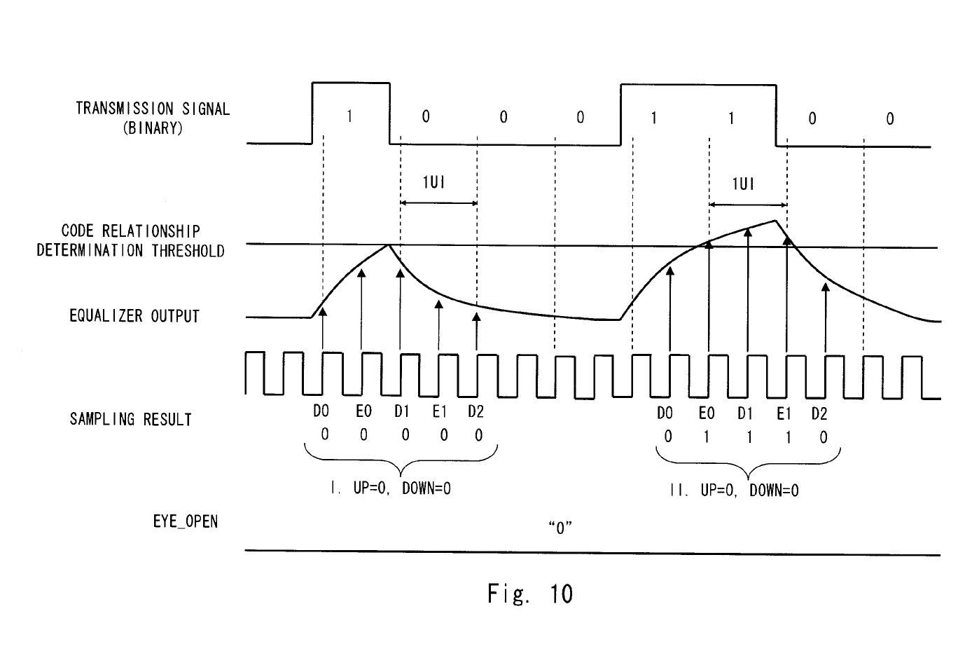

FIG. 10 shows an example where an equalizer adjustment according to this embodiment is applied to the signal of FIG. 20. In the diagram, the eye open/close determinator 106 determines whether the eye of the signal outputted from the equalizer 101 is opened or closed and outputs EYE_OPEN=“0”. The sampling result (D0, E0, D1, E1, D2) of the one-bit isolated data portion I is (0, 0, 0, 0, 0), so EYE_OPEN is “0”. According to its logic operation table (FIG. 2), the code comparator 103 refrains from adjusting the equalizer intensity in this case. The sampling result (D0, E0, D1, E1, D2) in a two-bit isolated data portion II is (0,1,1,1,0), so EYE_OPEN is “0.” According to its logic operation table (FIG. 2), the code comparator 103 refrains from adjusting equalizer intensity in this case as well.

Performance of the above-mentioned process allows, even when a signal having its eye closed is inputted, adjusting the equalizer intensity on the basis of a determination as to whether the eye is opened or closed. This can prevent an erroneous reduction in equalizer intensity with respect to a signal having its eye closed.

A second embodiment of the present invention is characterized in that the code comparator 103 is additionally provided with a control function that, when the eye of a signal to be adjusted is closed, increases the equalizer intensity compulsorily.

In the equalizer intensity automatic adjustment operation (FIG. 3) described in the first embodiment, a determination is made with reference to the signal outputted from the eye open/close determinator (S306), and when the eye is closed, (EYE_OPEN=“0”), the equalizer intensity is not adjusted. This can prevent the equalizer intensity from being erroneously reduced regardless of the fact that ISI jitter has yet to be sufficiently compensated for by the equalizer. In the equalizer adjustment method according to the first embodiment, however, the equalizer intensity is not automatically increased even in a case where it must be increased actually.

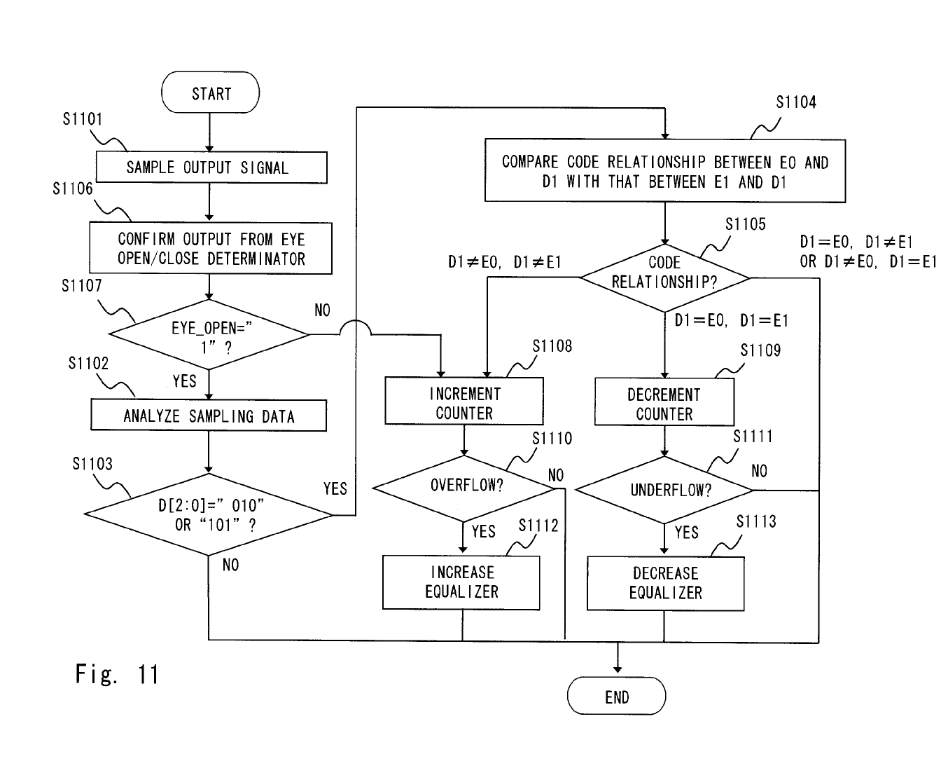

FIG. 11 shows the flowchart of an equalizer intensity automatic adjustment operation according to the second embodiment. The difference between the equalizer intensity automatic adjustment operation according to this embodiment and that according to the first embodiment will be described.

Before analyzing sampling data (S1102), the code comparator 103 makes a determination as to the signal outputted from the eye open/close determinator 106, that is, determines whether EYE_OPEN=“1” (S1107). If the code comparator 103 determines that the eye is closed (EYE_OPEN=“'0”), it compulsorily inputs UP=“1” into the up/down counter 104 (S1108). If the eye is closed, the process described in the first embodiment is performed to increase the equalizer intensity until the eye is opened (EYE_OPEN=“1”). If the eye is opened (EYE_OPEN=“1”), analysis of the sampling data (S1102) and the comparison between codes (S1104) are performed as in the first embodiment to adjust the equalizer intensity.

Incidentally, in the equalizer intensity automatic adjustment operation (FIG. 3) according to the first embodiment, the eye open/close output check (S306, 5307) exists between the code relationship check (S905) and counter decrement (S309). On the other hand, in the equalizer intensity automatic adjustment operation (FIG. 11) according to this embodiment, eye open/close output check (S306, 5307) does not exist. Since EYE_OPEN is “1” when reaching the code relationship check (S1105) process, performing eye open/close output check again is redundant and the check is therefore omitted.

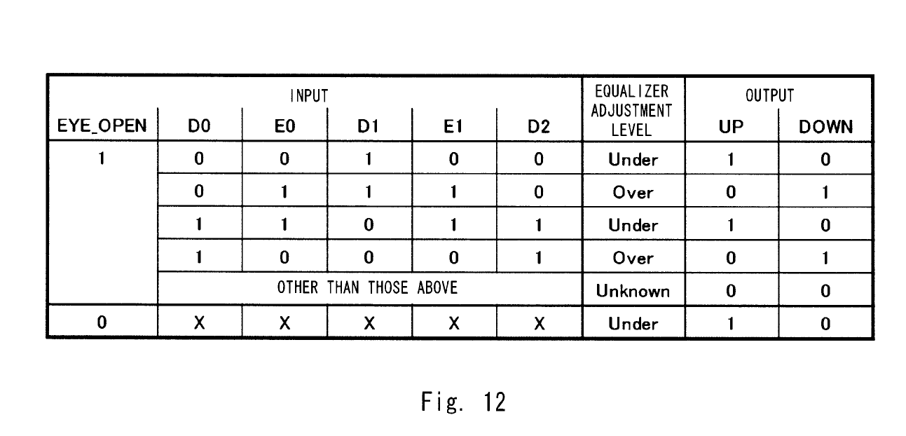

The equalizer intensity automatic adjustment operation according to the second embodiment (FIG. 11) can be realized by causing the code comparator 103 to operate according to the logic operation table shown in FIG. 12. Performance of the above-mentioned process allows, when the eye of a signal to be adjusted is closed, increasing the equalizer intensity compulsorily until the eye is opened.

### Third Embodiment

A third embodiment of the present invention is characterized in that it realizes the auto gain control (AGC) function of, regardless of the amplitude of an input signal, keeping constant the amplitude of a signal outputted from the equalizer, that is, adjusting the amplitude gain automatically.

In general, when an input signal has a small amplitude, control for increasing the gain is performed to increase the amplitude of an output signal. However, if the gain is kept high even when an input signal has a large amplitude, an output signal is limited.

In this case, when a linear system such as decision feedback equalizer (DFE) is connected to the stage subsequent to the equalizer 101 according to the first embodiment, the once-limited signal may be processed less effectively. For this reason, the AGC function is required to secure the dynamic range of a signal inputted into the subsequent circuit.

When an input signal has a small amplitude, the AGC function increases the gain to increase the amplitude of a signal outputted from the equalizer. In contrast, when an inputted signal has a large amplitude, the AGC function reduces the gain to restrict the amplitude of an output signal so that the dynamic range of a signal inputted into the subsequent circuit is not exceeded. Performance of such a process keeps the amplitude of an output signal within a given range.

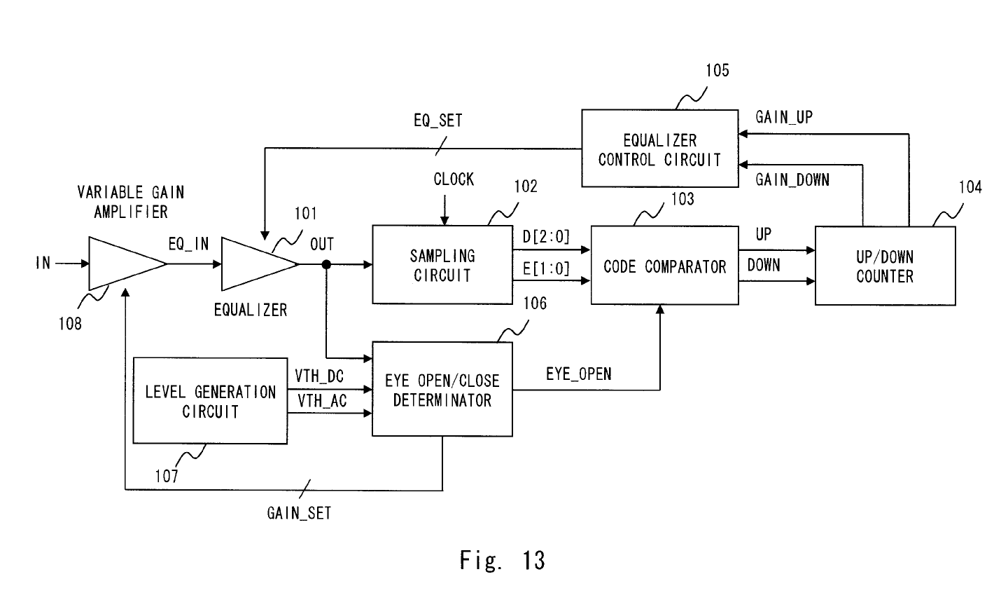

FIG. 13 is a diagram showing the basic configuration of an equalizer adjustment method that realizes the AGC function. Unlike the basic configuration of the first embodiment, the basic configuration of the third configuration includes a variable gain amplifier 108. The settings of the level generation circuit 107 are constant, and VIH_DC and VTH_AC are fixed to given levels. The signal outputted from the eye open/close determinator 106, VTH_SET, is inputted into the variable gain amplifier 108 as GAIN_SET.

The variable gain amplifier 108 is configured so that the amplitude gain monotonously varies with changes in the GAIN_SET signal (gain setting) from the eye open/close determinator 106.

The equalizer intensity automatic adjustment operation according to this embodiment is the same as that of the first or second embodiment (FIG. 3 or 11) and will not be described.

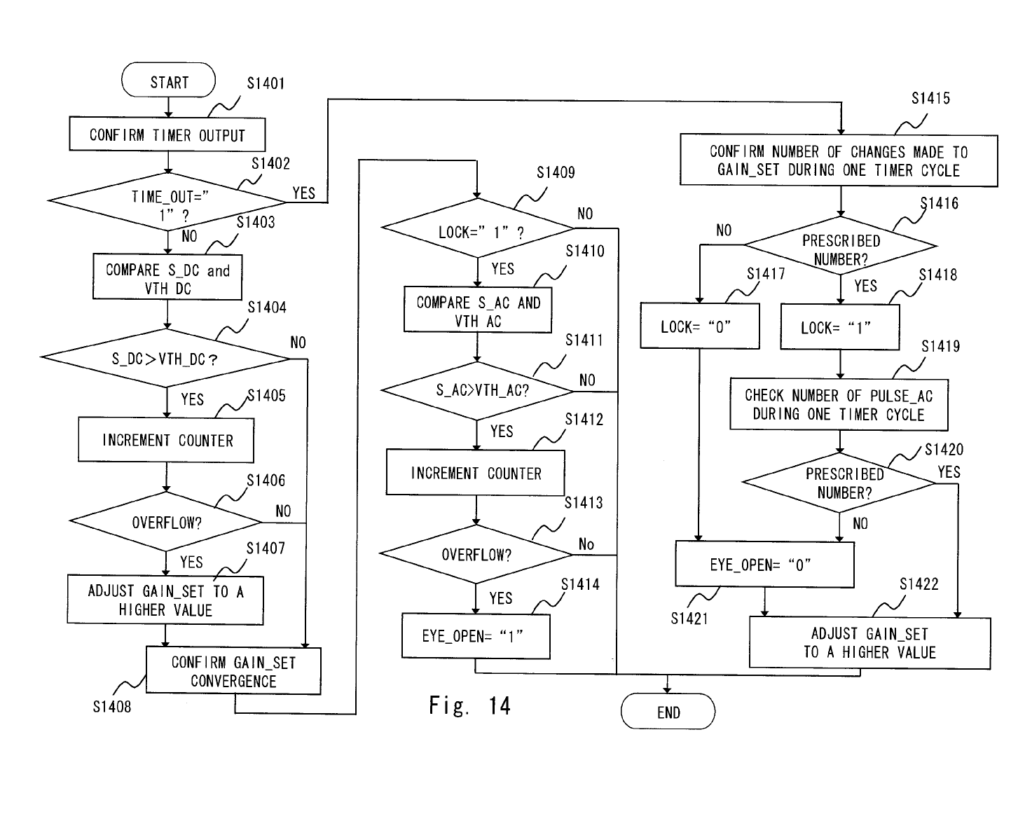

FIG. 14 is the flowchart showing the operation of an eye open/close determinator 106 according to this embodiment. In the operation of the eye open/close determinator 106 according to the second embodiment, the VTH_SET adjustment (S807, 5822) and the VTH_DC convergence check/detection (S808, S815) are performed. On the other hand, in the operation of the eye open/close determinator 106 according to this embodiment, the VTH_SET adjustment (S1407, S1422) and GAIN_SET convergence check/detection (S1408, S1415) are performed.

In this embodiment, a counter 1065 changes the value of GAIN_SET each time PULSE_DC is inputted (P=1). When receiving PULSE_AC one or more times, a convergence detection circuit 1066 determines that the eye is opened (Q=1). The convergence determination condition set for the variable gain amplifier is “the number of changes made to the output signal by the counter 1065 during one cycle of a TIME_OUT signal is one (n=1).”

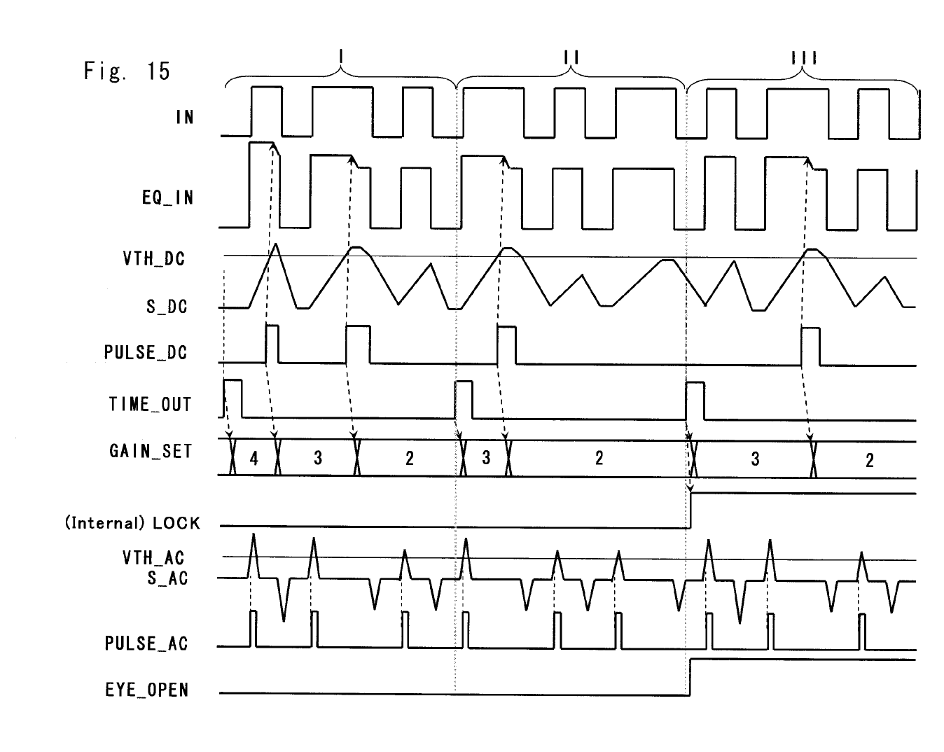

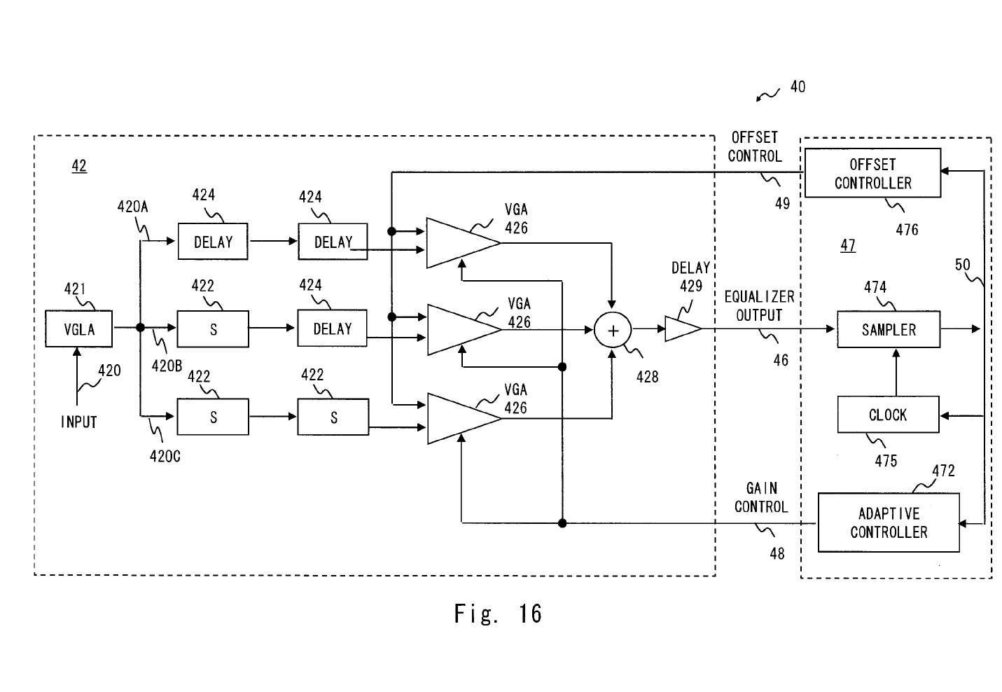

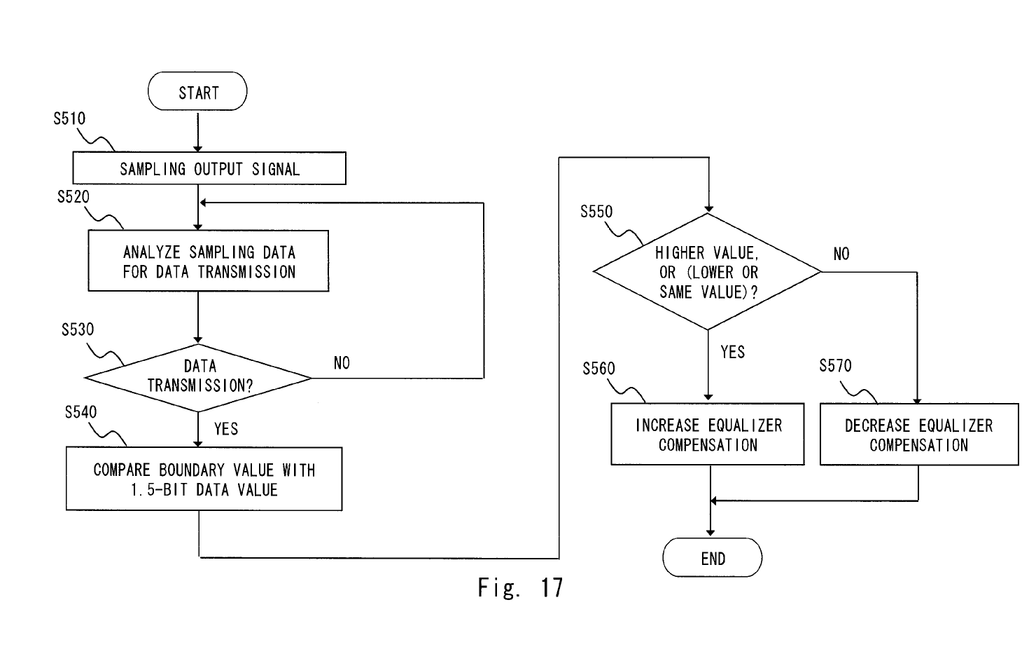

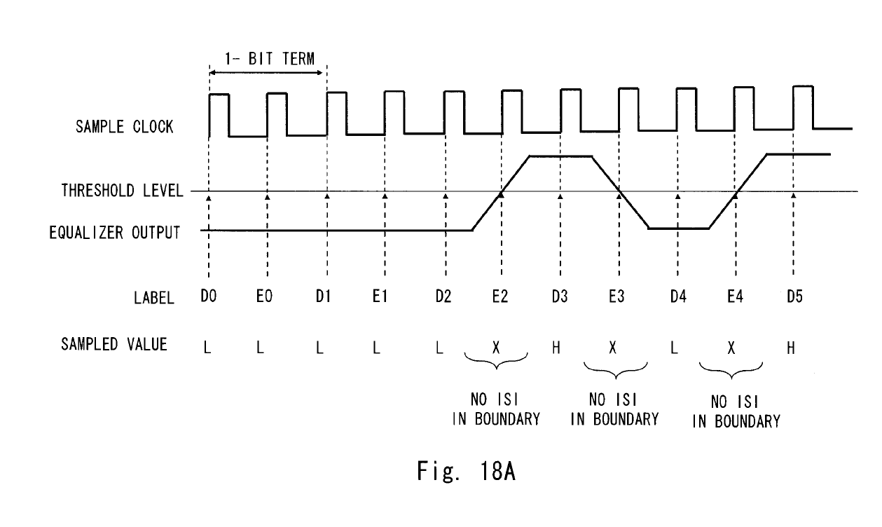

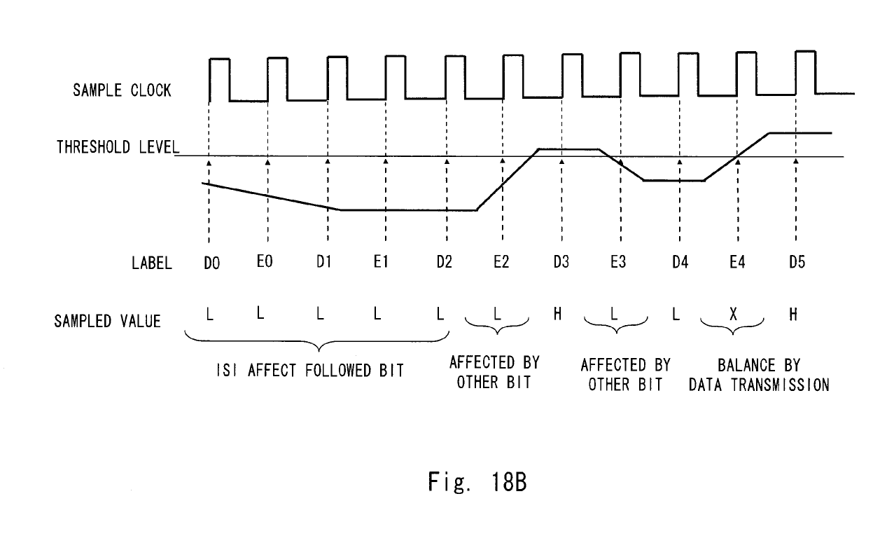

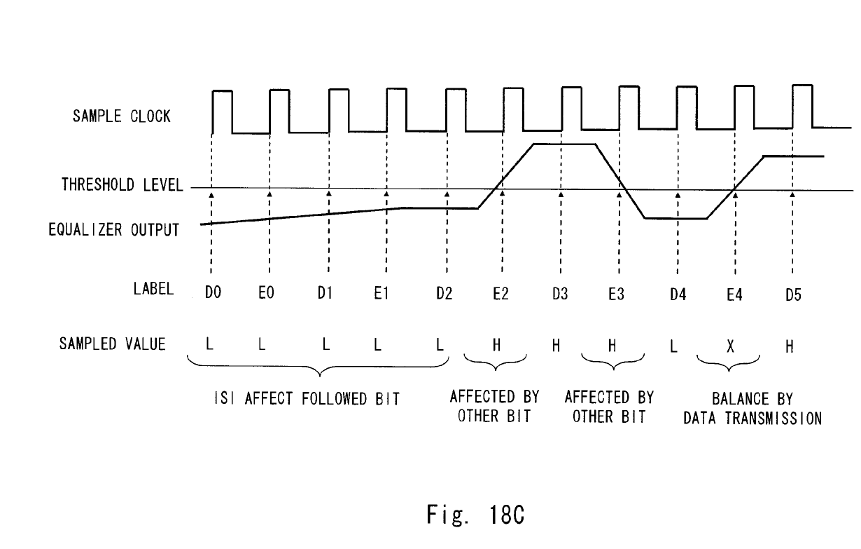

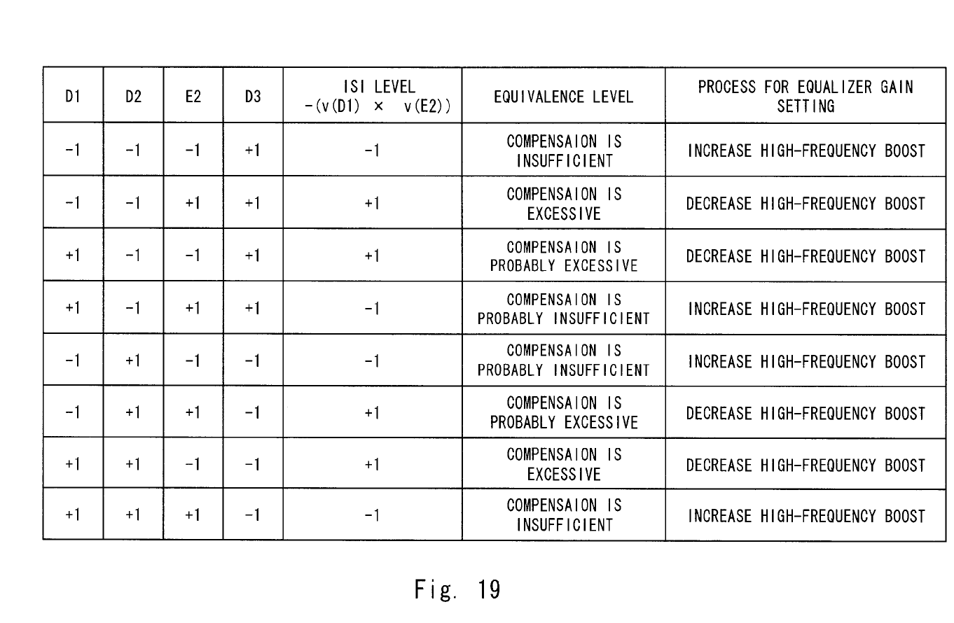

The operation of the eye open/close determinator 106 according to this embodiment performs will be described with reference to the timing chart of FIG. 15. FIG. 15 shows the operation of the eye open/close determinator 106 in three cycles (I, II, and III of FIG. 15) of the TIME_OUT signal.

The operation of the eye open/close determinator 106 in the I cycle of FIG. 15 will be described. As in the first embodiment, when the peak level of S_DC exceeds VTH_DC, the comparator 1063 outputs PULSE_DC to the counter 1065.

Upon receipt of PULSE_DC, the counter 1065 changes GAIN_SET to a lower value “3” so as to reduce the gain of the variable gain amplifier 108. The reduction in the gain of the variable gain amplifier 108 reduces the amplitude of a signal EQ_IN to be inputted to the equalizer and the amplitude of a signal OUT outputted from the equalizer. Similarly, when the peak level of S_DC exceeds VTH_DC, the comparator 1063 outputs PULSE_DC to the counter 1065 again. Upon receipt of PULSE_DC, the counter 1065 changes GAIN_SET to a lower value “2” again so as to reduce the gain of the variable gain amplifier 108 again.

In the cycle I of FIG. 15, the peak level of S_AC exceeds VTH_AC and therefore the comparator 1064 outputs PULSE_AC to the convergence detection circuit 1066. In this case, LOCK=“0”, so the convergence detection circuit 1066 outputs EYE_OPEN=“0”.

Next, the operation of the eye open/close determinator 106 in the cycle II of FIG. 15 will be described. A timer 1067 inputs a TIME_OUT signal into the counter 1065. Upon receipt of the TIME_OUT signal, the counter 1065 changes GAIN_SET to the one-step-higher value “3”. This increases the gain of the variable gain amplifier 108, thereby increasing the amplitude of the input signal EQ_IN and the amplitude of the output signal OUT.

Since the counter 1065 have changed the setting of GAIN_SET twice (“4“−”3“−”2”) in the cycle I of FIG. 15, the convergence detection circuit 1066 determines that the variable gain amplifier setting level has not converged yet. Accordingly, the value of LOCK is not changed (LOCK=“0”).

When the peak level of S_DC exceeds VTH_DC, the comparator 1063 outputs PULSE_DC to the counter 1065. Inputting PULSE_DC changes GAIN_SET to the one-step-lower value “2”. This reduces the gain of the variable gain amplifier 108. Subsequently, the peak level of S_DC no longer exceeds VTH_DC, so the comparator 1063 does not output PULSE_DC after this cycle.

In the cycle II of FIG. 15, the S_AC peak level exceeds VTH_AC and therefore the comparator 1064 outputs PULSE_AC to the convergence detection circuit 1066. In this case, LOCK=“0”, so the convergence detection circuit 1066 outputs EYE_OPEN=“0”, as in the cycle I of FIG. 15.

Next, the operation of the eye open/close determinator 106 in the cycle III of FIG. 15 will be described. As in the cycle II of FIG. 15, upon receipt of the TIME_OUT signal, the counter 1065 changes GAIN_SET to the one-step-higher value “3”.

Since the counter 1065 have changed the setting of GAIN_SET once (“3“−”2”) in the cycle II of FIG. 15, the convergence detection circuit 1066 determines that the variable gain amplifier setting level has converged. Accordingly, the convergence detection circuit 1066 changes the value of LOCK to “1” (LOCK=“1”).

When S_AC exceeds VTH_AC, the comparator 1064 outputs PULSE_AC to the convergence detection circuit 1066. Since the convergence detection circuit 1066 receives PULSE_AC when LOCK=“1”, it determines that the eye is opened, and outputs EYE_OPEN=

Performance of the above-mentioned process allows the peak amplitude of S_DC to, when the variable gain amplifier setting converges (LOCK=“1”), converge on VTH_DC, which is set to the given level. This means that the amplitude of the signal outputted from the equalizer has been adjusted to a given level, that is, the AGC function has been performed.

While the equalizer 101 is disposed in the stage subsequent to the variable gain amplifier 108 in the configuration shown in FIG. 13, the configuration is not limited thereto. Even when the variable gain amplifier 108 is disposed in the stage subsequent to the equalizer 101, the same function is performed. The present invention is not limited to the above-mentioned embodiments and changes can be made thereto as appropriate without departing from the spirit and scope of the invention.

The first, second, and third exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. An equalizer adjustment method for adjusting a characteristic of an equalizer, the equalizer adjusting a level of an input signal, the equalizer adjustment method comprising:
selecting a first timing on the basis of a data transition of the input signal and selecting second and third timings in accordance with cycles of the input signal, the second timing being a given time before the first timing, the third timing being a given time after the first timing;
performing sampling of the input signal at the first timing;
detecting three-bit data from sampling data extracted in the sampling at the first timing, the three-bit data being data where values of adjacent data bits differ from one another;
performing sampling of the input signal at the second timing;
performing sampling of the input signal at the third timing;
making a determination as to whether a waveform of the input signal has an opening; and
when the three-bit data is detected, adjusting the equalizer characteristic with reference to a value obtained in the sampling performed at the first timing, a value obtained in the sampling performed at the second timing, a value obtained in the sampling performed at the third timing, and the determination as to whether the waveform has an opening.

2. The equalizer adjustment method according to claim 1, wherein
in a first case where a code value of the value obtained in the sampling performed at the first timing and code values of the values obtained in the sampling performed at the second and third timings differ from one another, the equalizer intensifies emphasis of high-frequency components,
in a second case where the code value of the value obtained in the sampling performed at the first timing and the code values of the values obtained in the sampling performed at the second and third timings are the same as one another and it is determined in the determination step that the waveform has an opening, the equalizer weakens emphasis of high-frequency components, and
the equalizer characteristic is not adjusted in cases other than the first and second cases.

3. The equalizer adjustment method according to claim 2, wherein in a case where it is determined in the determination step that the waveform has no opening, the equalizer intensifies emphasis of high-frequency components.

4. The equalizer adjustment method according to claim 1, wherein a gain is calculated from a signal outputted from the equalizer and a given reference potential, and an amplitude of the outputted signal is automatically adjusted using the gain.

5. The equalizer adjustment method according to claim 1, wherein whether the waveform has an opening is determined based on a comparison between a proportion of a peak value of high-frequency components of the input signal and a proportion of a peak value of low-frequency components thereof.

6. An adaptive equalizer that adjusts a level of an input signal, the adaptive equalizer comprising:
an equalizer that adjusts a characteristic of the adaptive equalizer;
a sampler that selects a first timing on the basis of a data transition of the input signal, selects second and third timings in accordance with cycles of the input signal, the second timing being a given time before the first timing, the third timing being a given time after the first timing, and performs sampling of the input signal at the first, second, and third timings;
an eye open/close determinator that makes a determination as to whether a waveform of the input signal has an opening;
a code comparator that detects three-bit data from data extracted in the sampling performed at the first timing, the three-bit data being data where values of adjacent data bits differ from one another, and when the three-bit data is detected, and outputs a determination signal for adjusting the equalizer characteristic, with reference to a value obtained in the sampling performed at the first timing, a value obtained in the sampling performed at the second timing, a value obtained in the sampling performed at the third timing, and the determination as to whether the waveform has an opening; and
an equalizer control circuit that outputs a level adjustment signal to the equalizer on the basis of the determination signal.

7. The adaptive equalizer according to claim 6, wherein
in a first case where a code value of the value obtained in the sampling performed at the first timing and code values of the values obtained in the sampling performed at the second and third timings differ from one another, the code comparator outputs a signal for causing the equalizer to intensify emphasis of high-frequency components,
in a second case where the code value of the value obtained in the sampling performed at the first timing and the code values of the values obtained in the sampling performed at the second and third timings are the same as one another and where it is determined in the determination that the waveform has an opening, the code comparator outputs a signal for causing the equalizer to weaken emphasis of high-frequency components, and
the code comparator does not output a signal for adjusting the equalizer characteristic in cases other than the first and second cases.

8. The adaptive equalizer according to claim 7, wherein when determining in the determination that the waveform has no opening, the code comparator outputs a signal for causing the equalizer to intensify emphasis of high-frequency components.

9. The adaptive equalizer according to claim 6, further comprising
a feedback circuit that calculates a gain from a signal outputted from the equalizer and a given reference potential and automatically adjusts an amplitude of the outputted signal using the gain.

10. The adaptive equalizer according to claim 6, wherein the eye open/close determinator determines whether the waveform has an opening, based on a comparison between a proportion of a peak value of high-frequency components of the input signal and a proportion of a peak value of low-frequency components thereof.
